(19) United States
(12) Patent Application Publication
(10) Pub. No.: US 2024/0347350 A1
(43) Pub. Date: Oct. 17, 2024

(54) IN LINE WATER SCRUBBER SYSTEM FOR SEMICONDUCTOR PROCESSING

(71) Applicant: Edwards Vacuum LLC, Sanborn, NY (US)

(72) Inventor: Imad Mahawili, West Sussex (GB)

(21) Appl. No.: 18/681,957

(22) PCT Filed: Aug. 31, 2022
(86) PCT No.: PCT/IB2022/058168

§ 371 Date: Feb. 7, 2024

Related U.S. Application Data
(60) Provisional application No. 63/240,003, filed on Sep. 2, 2021.

(51) Int. Cl. H01L 21/67; B01D 53/18

(52) U.S. Cl. CPC H01L 21/67051; B01D 53/18; B01D 2252/103; B01D 2258/0216

(57) ABSTRACT

A semiconductor processing system includes a vacuum pump having an inlet and an outlet, with the inlet of the vacuum pump configured to be in fluid communication with an outlet of a semiconductor reactor, and with the vacuum pump configured to output an exhaust of waste gases from the reactor at the outlet of the vacuum pump. The semiconductor processing system further includes a water scrubber system at the outlet of the vacuum pump, which has a vertical orientation relative to the pump and has an inlet and at least one mixing chamber. The inlet is in fluid communication with the outlet of the vacuum pump and the mixing chamber. The scrubber system is configured to maintain the temperature of exhaust at the output of the pump, while the exhaust is directed to the mixing chamber, and to inject water into the exhaust to remove water reactive products in the exhaust.

### BACKGROUND

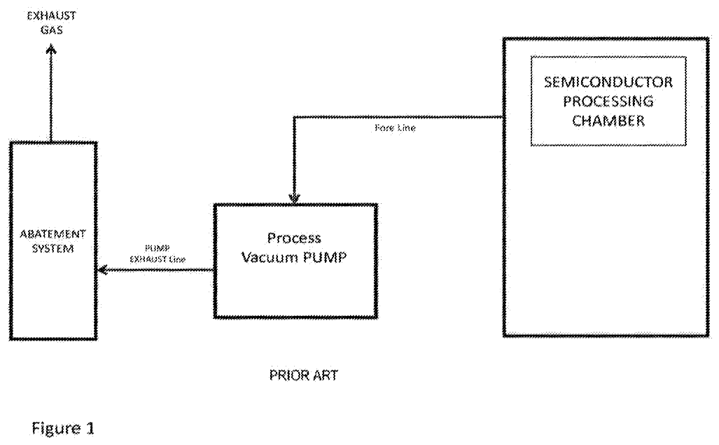

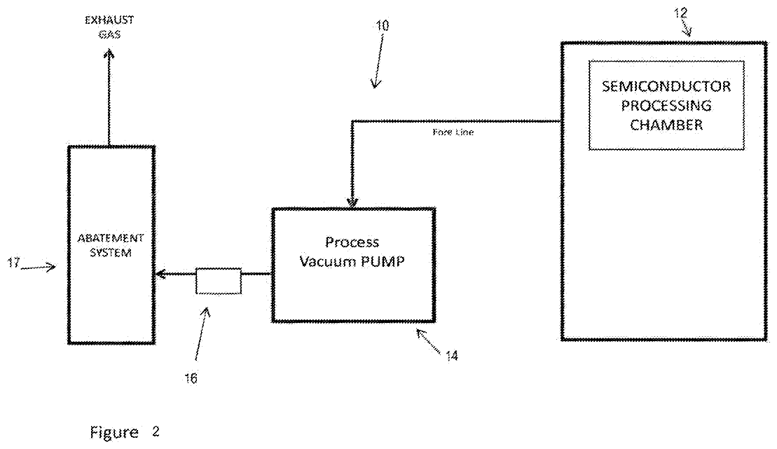

FIG. 1 shows a typical semiconductor processing system flow diagram. Semiconductor devices are created by the processing of single crystal silicon wafers through numerous steps using various chemical vapors under high vacuum. The utilization of these chemical vapors into the fabrication of the semiconductor device is not very efficient and consequently over fifty percent, or more, of the chemical vapors exit the processing chamber through the vacuum fore-line connected to the vacuum pump. The exhaust of the vacuum pump, which is at one atmosphere, is heavily diluted with nitrogen gas to prevent the possibilities of detonations in the case the chemical vapors are flammable. The pump exhaust line is typically heated to 100-200 C to prevent the condensation of the volatile chemical vapors. The nitrogen diluted chemical vapors then are destroyed in the abatement systems using high temperatures generated by either the combustion of methane gas or electric arc discharge.

Titanium tetrachloride, a liquid at room temperature, with a boiling point of 136.6 C and highly reactive with water, is used in the chemical vapor deposition of titanium nitride thin film when reacted with ammonia gas. When titanium tetrachloride is used in semiconductor processing the pump exhaust composition would consist of unreacted titanium tetrachloride and ammonia gas in nitrogen and other chemical byproducts. The pump exhaust line could 15 to 40 feet long or longer. Any cold spot in this line would result in the condensation of titanium tetrachloride. This can lead to hazardous conditions due the accumulation of liquid chemicals that can undergo subsequent reactions and cause localized corrosion in the pump exhaust line should there be any water condensation either during processing or routine maintenance.

Tungsten hexafluoride, boiling point of 17 C, is reactive with water and is widely used in semiconductor processing. Dilution with nitrogen and heating of the pump exhaust line is critical for safe and continuous operation.

Ammonium nitrate, boiling point of 210 C and melting point of 169.6 C, is the product of various chemical vapor phase reactions that can take place in the processing chamber or along the fore-line. If the pump exhaust line is not heated to 250 C, ammonium nitrate can condense and deposit. The accumulation of this chemical in the pump exhaust line can create localized deposits that can detonate spontaneously under both chemical reactions with pump exhaust gases or due to friction/vibration of the exhaust line, e.g. during maintenance schedules.

Advanced semiconductor processing employ atomic layer deposition of aluminum oxide. The typical chemical vapor source for such deposition is trimethyl aluminum (TMA), boiling point of 125-130 C, and reacts aggressively with water. In these processes the pump exhaust line must be heated very uniformly to at least 200 C. Any cold spot in the line would result in the condensation of TMA creating an extremely hazardous maintenance procedure that is both dangerous and costly. It is widely reported that TMA condenses at the entrance of the abatement systems causing plug-in input tubes and increased and hazardous maintenance issues.

Furthermore, chlorine trifluoride (CIF3), used in some special processes for chamber cleaning, can be found in the pump exhaust line. CIF3 is very highly reactive with water and presents a dangerous and costly maintenance procedures.

### DETAILED DESCRIPTION OF THE DRAWINGS

FIG. 1 is a schematic drawing of a prior art semiconductor processing system with an abatement system in the vacuum pump exhaust line;

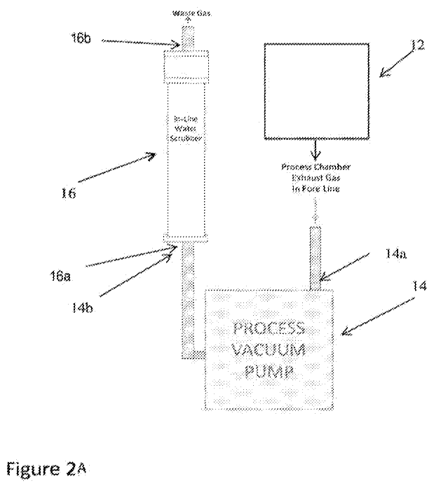

FIG. 2 is a schematic drawing of a semiconductor processing system with a post pump in-line water scrubber system:

FIG. 2A is a schematic drawing of the semiconductor reactor, the semiconductor processing system pump, and the post pump in-line water scrubber system located at the outlet of the pump in a vertical arrangement:

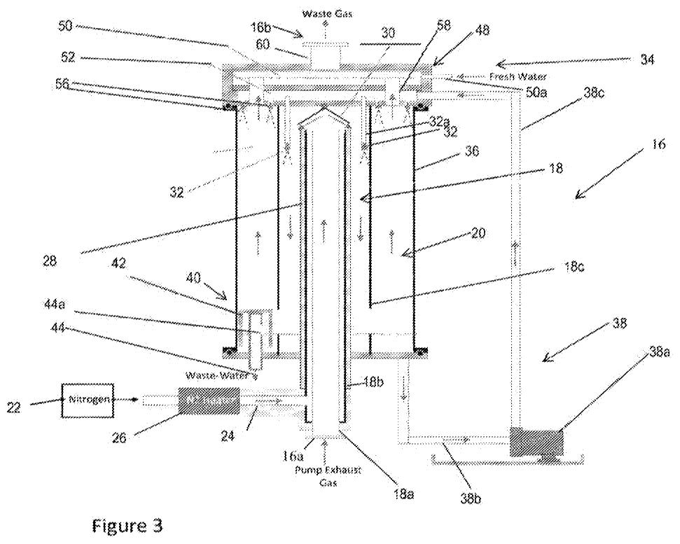

FIG. 3 is a detailed cross-section view of the water scrubber system of FIG. 2A; and

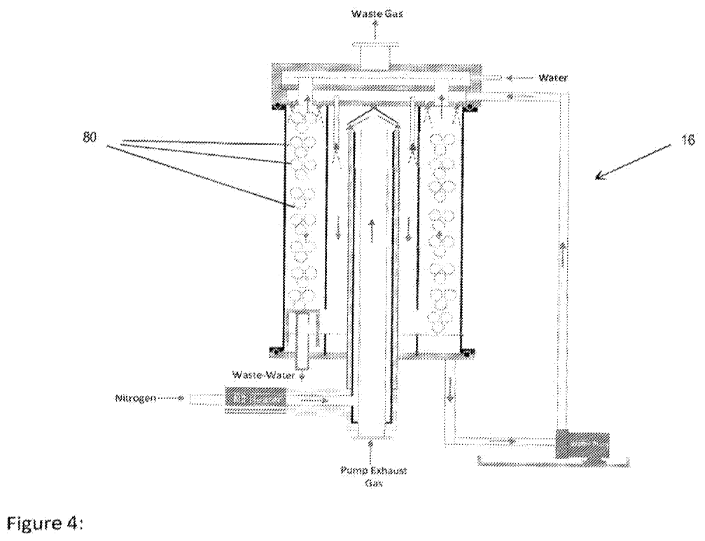

FIG. 4 is a detailed cross-section view of the water scrubber system of FIG. 2A with an enhanced mass transfer surface area.

### DETAILED DESCRIPTION

Referring to FIG. 2, the numeral 10 generally designates a semiconductor processing system. Semiconductor processing system 10 includes a semiconductor reactor 12, a vacuum pump 14, an in-line water scrubber system 16 that is installed at the vacuum pump outlet 14b (of FIG. 3), and an abatement system. To efficiently remove at least one or more, and optionally most, if not all, of the water reactive chemicals, the in-line water scrubber system 16 is located at the outlet of the pump, for example, within 12 inches or 6 inches of the horizontal portion of the pump output elbow and, further, is located in a vertical orientation at the outlet of the pump. As will be more fully described below, the in-line water scrubber system 16 is configured to efficiently remove at least one or more, and optionally most, if not all, of the water reactive chemicals, such as titanium tetrachloride, tungsten hexafluoride, ammonium nitrate, trimethyl aluminum, chlorine trifluoride and other vapors that readily react and or are absorbed with/by water, from the pump exhaust output (waste gas(es) from reactor 12). It may also remove acid gases and ammonia gas due to their high water solubility.

As best seen in FIGS. 2A and 3, in-line water scrubber system 16 includes an inlet 16a, which is coupled to the vacuum pump output 14b of FIG. 2A, and an outlet 16b that exhausts the abated waste gas. In-line water scrubber system 16 includes a first mixing chamber 18 and a second mixing chamber 20. As described more fully below, first mixing chamber 18 maintains the heat of the exhaust gas coming into the in-line water scrubber system and mixes heated nitrogen with the waste gas, while the second chamber 20 mixes the mixture of heated nitrogen and waste gas with water to react with the water reactive chemical vapors of the waste gas(es).

As best seen in FIG. 3, first mixing chamber 18 is formed by three concentric conduits 18a, 18b, and 18c, such a cylindrical tubes. Suitable material for conduits 18a, 18b, and 18c include metal, such as stainless steel 304 or 316 or other alloys. Conduits 18a, 18b, and 18c may also be constructed out of polymer materials, such as polypropylene, polyethylene, teflon or other plastics provided that the operating temperature is below the yield/melt point of the polymer. Conduit 18a, which has a vertical orientation relative to the outlet of pump 14, is fluid communication with the pump outlet through one end, which forms the inlet for conduit 18a and forms inlet 16a of in-line water scrubber system 16, and is concentrically placed within conduit 18b. Thus, conduit 18b also has a vertical orientation. For example, the diameter of conduit 18a may be about 2 to 4 inches and typically about 2.5 inches. The diameter of conduit 18b is about an inch larger than conduit 18c and typically in a range of 3 to 5 inches and optionally about 3.5 inches. Both conduits 18a and 18b may be cylindrical with a constant diameter along their entire length.

To help maintain the temperature of the exhaust from the pump, conduit 18b is configured to heat conduit 18a. For example, heated nitrogen flows between the space between the two conduits 18a and 18b to heat conduit 18a and the waste gas flowing there through, and thereafter mixes with the waste gas flowing from conduit 18a to form a heated nitrogen diluted mixture. For example, conduit 18b may be in fluid communication with a supply of nitrogen 22 via a conduit 24, which is heated by a nitrogen heater, such as conventional nitrogen heater, located in-line in conduit 24. For example, the nitrogen is heated to a temperature in a range of between room temperature and 250 C, but typically in the range of 150 to 200 C to thereby heat conduit 18a to at least 150 to 200 C.

Conduit 24 is in fluid communication with a lower end of conduit 18a adjacent and optionally immediately adjacent the inlet of conduit 18a, which as noted forms inlet 16a of in-line water scrubber system 16. In this manner the temperature of the exhaust output (waste gas(es)) from pump 14 remains generally constant. To further assist in maintaining the elevated temperature of conduit 18a and the waste gas therein, conduit 18a may be insulated by a layer of insulation 28. Suitable insulation may be formed from a sheath of fiber glass or quartz wool or any off-the-shelf insulating materials. The insulation may also extend over conduit 24 to help maintain the elevated temperature of the nitrogen. The heated nitrogen gas may be introduced into conduit 18b at a flow rate range of 5 to 30 standard liters per minute or more. The injection of heated nitrogen in this manner and at this location ensures that the pump exhaust (waste gas(es)) stays at its high exhaust temperature preventing condensation of the entrained chemical vapors within.

To mix the heated nitrogen with the waste gas, the upper ends of both conduits 18a and 18b are open and have terminal ends at or about the same location (or height when in a vertical orientation). For example, each conduit 18a, 18b may have a length or height in a range of about 24 to 48 inches or longer depending on the specific vapors to be removed/reacted/absorbed. Thus, after the heated nitrogen flows through conduit 18b and heats conduit 18a (and the waste gas thereon) it then mixes with the waste gas flowing from the open upper end of conduit 18a. After mixing, the mixture is then directed to a larger mixing area formed by conduit 18c to allow the mixture to expand and slow down in velocity.

In the illustrated embodiment, conduit 18c surrounds and is spaced from conduit 18b. Conduit 18c is also installed concentrically along its entire length and formed by yet another larger diameter cylindrical tube, typically 1-4 inches or more larger than conduit 18b, for example about 4 to 9, and optionally 7.5 inches in diameter. Hence, a larger mixing area may be formed between conduit 18c and conduit 18b. To direct the mixture into conduit 18c, mixing chamber 18 may include a deflector 30 to deflect the mixture of heated nitrogen and waste gas downwards (in the vertical orientation shown).

In the illustrated embodiment, deflector 30 comprises a conical surface, e.g. formed from a conical plate, which is mounted to or formed at the upper closed end of conduit 18c. For example, the conical surface is angled so that as the heated nitrogen and waste gas(es) mix (as they exit their respective conduits) they impinge on the conical surface, which causes the mixture to change flow direction from vertically upwards to downwards and at an angle between about 30 to 60 degrees, as noted, allowing this gas mixture to expand.

Referring again to FIG. 3, water is directed into chamber 18 and, more specifically, into the larger mixing area in conduit 18c to react with the water reactive chemical vapors of the pump exhaust waste gases. Further, water fills the bottom of chamber 18 and chamber 20. In the illustrated embodiment, water is injected into conduit 18c via venturi nozzles 32, for example, helical venturi nozzles, which direct and inject water into chamber 18 from a water distribution header 34, which is mounted above chambers 18 and 20. In the illustrated embodiment, water distribution header 34 includes a housing 48, which as described below, closes the upper end of conduit 18c with the exception of the venturi nozzles noted above.

Second chamber 20 may be similarly formed by another coaxial conduit 36, which is concentrically mounted about conduit 18c beneath water distribution header 34. Conduit 36 is also installed concentrically along its entire length and formed by yet another larger diameter cylindrical tube, typically 1 to 4 inches or more larger than conduit 18c, for example from about 5 to 13 inches or about 11.5 inches in diameter. The space between conduit 36 and conduit 18c forms second mixing chamber 20. Second mixing chamber 20 is configured to mix the water with any remaining water reactive chemical vapors of the pump exhaust waste gases.

In-line water scrubber system 16 also includes a water recirculating circuit 38 to circulate water through the mixing chambers. In the illustrated embodiment, water recirculating circuit 38 includes a recirculating pump 38a, such as a high capacity magnetically couple water pump, which can pump, for example, 10 to 25 gallons per minutes. The pump's intake is in fluid communication via conduit 38b with mixing chamber 20 at its lower end, and the pump's output is in fluid communication with water distribution header 34 via conduit 38c. Thus, pump 38a can withdraw water from the bottom of chamber 20 and redirect to the water distribution header 34, which in turn directs water in to chamber 18 and 20, via the venturi nozzles noted above and additional venturi nozzles noted below.

Additionally, pump 38a can maintain the water level in mixing chamber 20, as well as mixing chamber 18, at a given level using a level controller 40. In the illustrated embodiment, level controller 40 includes a cover 42 and drain tube 44 with a side opening 44a (FIG. 3). The water height is controlled by the height of the drain tube opening within the level controller as shown.

Referring again to FIG. 3, as noted, water distribution header 34 includes a housing 48. Housing 48 includes two chambers 50 and 52—for example, upper and lower chambers—with chamber 52 distributing water to mixing chambers 18 and 20. Fresh water is introduced into chamber 50 via inlet 50a, which slightly mixes with the scrubbed waste gas from chamber 18 and 20 for discharge into the pump exhaust line upstream of the in-line water scrubber system.

Water circulating circuit 38 is in fluid communication with chamber 52, which is in fluid communication with mixing chamber 18 via venturi nozzles 32 (noted above) and with mixing chamber 20 via venturi nozzles 56. Nozzles 56 may also comprise helical venturi nozzles, which are mounted to the lower wall of housing 48 and which are mounted over the open ends of conduits 18b, 18c, and 36 similar to nozzles 32. Nozzles 56 are located over the spaced between conduit 36 and conduit 18c and spray water at larger angles than nozzles 32, for example, in a range of about 90 to 150 degrees and, optionally, about 120 degrees.

Housing 48 is mounted to the upper ends (as viewed in FIG. 3) of conduits 18b and 18c and 36 to thereby close the upper ends of the conduits and thereby form the respective chambers. Chamber 20 is in fluid communication with chamber 50 of water distribution header 34 via outlets 58, which extend or pass through chamber 52 and discharge the cleaned waste gas to chamber 50, which then discharges the cleaned waste gas via outlet 16b, which may be formed by a flanges pipe 60 for connection to the pump exhaust line. Fresh water is introduced into chamber 50 via inlet 50a, which slightly mixes with the scrubbed waste gas from chamber 20 for discharge into the pump exhaust line upstream of the in-line water scrubber system.

Pump 38a of water recirculating circuit 38 recirculates the water at high flow and pressure into the chamber 52 of the water distribution header 34. The recirculating water into chamber 18 may be injected from chamber 52 through several tubes 32a, between 4 to 8, and typically 6 depending on the specific scrubber system design, with the venturi nozzles 32 mounted at the end of the respective tubes. Venturi nozzles 32 may spray the water at an angle between about 30 to 60 degrees and typically about 50 degrees into chamber 18. This rotational high water flow velocity mixes rapidly at a narrow angle with the deflected hot nitrogen and waste gas. It is in this first mixing chamber 18 of the in-line water scrubber system that the water reacts with the water reactive chemical vapors of the pump exhaust gases.

The nitrogen and waste gas(es) that no longer contain the reactive water chemicals then turn upwards as shown and pass at even lower flow velocity as they traverse upwards through the second mixing chamber 20 of the scrubber. These gases are further scrubbed by a recirculating water flowing through venturi nozzles 56 that spray water, as noted, at larger angles in the range of 90 to 150 degrees and typically 120 degrees. The residual nitrogen and permanent gases of the pump waste gas then pass through 4 to 6 tubes, which form outlets 58, as shown, to the chamber 50 of the water distribution header 34

Fresh water may continuously be added via inlet 50a of chamber 50 at the rate of the water removed as waste-water.

The exhaust gas of the in-line scrubber system mostly consists of nitrogen and permanent gases, such as carbon dioxide, oxygen, ozone, hydrogen, PFCs and others depending on the specific semiconductor process. This scrubber system exhaust gas then passes through the pump exhaust line at one atmosphere and to an abatement system for final destruction of harmful gases before exhausting the atmosphere.

Referring to FIG. 4, in-line water scrubber system 16 may also include a plurality of rings 80, such as Raschig rings, that are stacked in either mixing chamber 20 or mixing chamber 18 or both chamber 20 to enhance the mass transfer surface area. The rings may be formed from a variety of different materials compatible with the chemical vapors in the pump exhaust to increase the mass transfer surface area, as noted, and to increase the absorption of acid gases and ammonia.

This novel in-line water scrubber is ideally installed immediately at the pump outlet (for example, within 12 inches or within 6 inches of the horizontal portion of the pump outlet elbow) so that most, if not all, these water reactive chemicals can be removed by the water and water reactions byproducts, such solid oxides and acids and base solutions, can be sent to the waste-water drain before they enter the pump exhaust line. Thus, this in-line water scrubber assembly offers significant safety and cost advantage to continuous processing operations at reduced maintenance intervals.

1. A semiconductor processing system comprising:
a vacuum pump having an inlet and an outlet, said inlet of said vacuum pump configured to be in fluid communication with an outlet of a semiconductor reactor, and said vacuum pump configured to output an exhaust of waste gases from the reactor at said outlet of said vacuum pump; and
a water scrubber system at said outlet of said vacuum pump, said water scrubber system having a vertical orientation relative to said vacuum pump and having an inlet and at least one mixing chamber, said inlet in fluid communication with said outlet of said vacuum pump and said mixing chamber, and said scrubber system configured to maintain the temperature of the exhaust at said output of said vacuum pump and while the exhaust is directed to said mixing chamber and to inject water into the exhaust to remove water reactive products in the exhaust.

2. The semiconductor processing system according to claim 1, wherein said water scrubber system includes a water recirculating circuit to recirculate water through said mixing chamber.

3. The semiconductor processing system according to claim 2, wherein said water recirculating circuit is configured to maintain a water level in said mixing chamber.

4. The semiconductor processing system according to claim 1, said water scrubber system including a plurality of Raschig rings.

5. The semiconductor processing system according to claim 1, further comprising a supply of heated nitrogen, said water scrubber system being in fluid communication with said supply of heated nitrogen.

6. The semiconductor processing system according to claim 5, wherein said supply of heated nitrogen is configured to heat the exhaust flowing to said mixing chamber.

7. The semiconductor processing system according to claim 6, wherein said water scrubber system includes a first conduit, said inlet of water scrubber system in fluid communication with said first conduit to direct the exhaust into said first conduit, and said first conduit directing the exhaust to said mixing chamber.

8. The semiconductor processing system according to claim 7, wherein said supply of heat nitrogen is directed to heat said first conduit and the exhaust flowing there through.

9. The semiconductor processing system according to claim 8, wherein said water scrubber system includes a second conduit surrounding said first conduit, and said supply of heated nitrogen is configured to flow the heated nitrogen between said second conduit and said first conduit to thereby heat said first conduit and the exhaust flowing there through.

10. The semiconductor processing system according to claim 9, wherein said water scrubber system includes a second conduit surrounding said first conduit, and said supply of heated nitrogen is configured to direct a flow of heated nitrogen between said second conduit and said first conduit to thereby heat said first conduit and the exhaust flowing there through.

11. The semiconductor processing system according to claim 10, wherein said water scrubber system is configured to mix the heated nitrogen with the exhaust to form a heated nitrogen diluted mixture after flowing through said first and second conduits and thereafter inject water into the heated nitrogen diluted mixture.

12. The semiconductor processing system according to claim 11, wherein said water scrubber system is configured to redirect the heated nitrogen diluted mixture into a larger portion of the mixing chamber to allow the heated nitrogen diluted mixture to expand and to inject the water when the heated nitrogen diluted mixture is flowed into said larger portion.

13. The semiconductor processing system according to claim 11, wherein said mixing chamber comprises a first mixing chamber, said water scrubber system including a second mixing chamber, and said first mixing chamber directing the heated nitrogen diluted mixture to said second mixing chamber.

14. The semiconductor processing system according to claim 13, wherein said water scrubber system is configured to inject water into the heated nitrogen diluted mixture in said first mixing chamber and said second mixing chamber.

15. The semiconductor processing system according to claim 13, wherein said water scrubber system is configured to inject water into the exhaust in said first mixing chamber using a first set of venturi nozzles.

16. The semiconductor processing system according to claim 15, wherein said water scrubber system is configured to inject water into the exhaust in said second mixing chamber using a second set of venturi nozzles wherein said first set of venturi nozzles spray water at a smaller angle than said second set of venturi nozzles.

17. The semiconductor processing system according to claim 16, wherein the first set of venturi nozzles spray the water into the first mixing chamber at angle between about 30 to 60 degrees and further optionally about 50 degrees into chamber, and the second set of venturi nozzles spraying the water into the second mixing chamber at angle between about 90 to 150 degrees and further optionally about 120 degrees.

18. An in-line water scrubber system comprising:
a mixing chamber;
an inlet for fluid communication with an outlet of a vacuum pump of a semiconductor processing system to receive exhaust from the outlet of the vacuum pump, and said inlet in fluid communication with said mixing chamber and configured to direct the exhaust to said mixing chamber;
a supply of heated nitrogen in fluid communication with said mixing chamber and configured to maintain the temperature of the exhaust while the exhaust is directed to said mixing chamber; and
a water supply configured to inject water into the exhaust in said mixing chamber to remove water reactive products in the exhaust.

19. The in-line water scrubber system according to claim 18, further comprising a first conduit, said inlet in fluid communication with said first conduit to direct the exhaust into said first conduit, and said first conduit directing the exhaust to said mixing chamber.

20. The in-line water scrubber system according to claim 18, wherein said supply of heated nitrogen is configured to heat said first conduit and the exhaust flowing there through to said mixing chamber.

21. The in-line water scrubber system according to claim 20, further comprising a second conduit surrounding said first conduit, and said supply of heated nitrogen being configured to flow the heated nitrogen between said second conduit and said first conduit to thereby heat the first conduit and the exhaust flowing there through.

22. The in-line water scrubber system according to claim 21, wherein said first and second conduits are configured to mix the heated nitrogen with the exhaust to form a heated nitrogen diluted mixture after flowing through said first and second conduits, and said water supply configured to inject the water into the heated nitrogen diluted mixture.

23. The in-line water scrubber system according to claim 22, wherein said water scrubber system is configured to redirect the heated nitrogen diluted mixture into a larger portion of said mixing chamber to allow the heated nitrogen diluted mixture to expand and to inject the water when the heated nitrogen diluted mixture is flowed into said larger portion.

24. The in-line water scrubber system according to claim 23, wherein said mixing chamber comprises a first mixing chamber, further comprising a second mixing chamber, and said first mixing chamber directing the heated nitrogen diluted mixture to said second mixing chamber.

25. The in-line water scrubber system according to claim 24, wherein said water supply is configured to inject water into the heated nitrogen diluted mixture in said first mixing chamber and said second mixing chamber.

26. The semiconductor processing system according to claim 25, wherein said water scrubber system is configured to inject water into the exhaust in said first mixing chamber with a first set of venturi nozzles and into said second mixing chamber with a second set of venturi nozzles, wherein optionally said first set of venturi nozzles spray water into said first mixing at a smaller angle than said second set of venturi nozzles.

27. A method of scrubbing semiconductor processing waste gases of a semiconductor processing system, the semiconductor processing system having a reactor, a vacuum pump for pumping waste gases from the reactor, the vacuum pump having an inlet and an outlet, said method comprising:
providing a mixing chamber having an inlet;
vertically orienting the mixing chamber relative to the vacuum pump;
providing fluid communication between the outlet of the vacuum pump and the inlet of the mixing chamber, and the scrubber system configured to maintain the temperature of exhaust at the output of the vacuum pump and while the exhaust is directed into the mixing chamber and to direct water into the exhaust thereby removing water reactive products and/or water absorbing products in the exhaust.

28. The method according to claim 27, wherein the outlet of the vacuum pump has an elbow with a horizontal component, further comprising locating the inlet to the mixing chamber within 12 inches of the horizontal component of the elbow.

29. The method according to claim 27, wherein further comprising heating the exhaust flowing to the mixing chamber.

30. The method according to claim 29, wherein said heating includes directing heated nitrogen to heat the exhaust flowing to the mixing chamber.

31. The method according to claim 30, further comprising mixing the heated nitrogen with the exhaust in the mixing chamber to form a heated nitrogen diluted mixture.

32. The method according to claim 31, further comprising directing the heated nitrogen diluted mixture and the water into the mixing chamber thereby removing water reactive products and/or water absorbing products in the heated nitrogen diluted mixture.

33. The method according to claim 32, wherein said mixing chamber comprises a first mixing chamber, further comprising a second chamber and directing the water and heated nitrogen diluted mixture into the second chamber.

34. The method according to claim 33, further comprising directing water into the second chamber and thereby removing further water reactive products and/or water absorbing products in the exhaust.

35. The method according to claim 32, wherein said directing water includes injecting the water with venturi nozzles.

36. The method according to claim 27, wherein said removing water reactive products includes removing a water reactive product selected from the group consisting of titanium tetrachloride, tungsten hexafluoride, ammonium nitrate, trimethyl aluminum, and chlorine trifluoride.

37. A method of scrubbing semiconductor processing waste gases of a semiconductor processing system, the semiconductor processing system having a reactor, a vacuum pump for pumping waste gases from the reactor, the vacuum pump having an inlet and an outlet, said method comprising:
providing a mixing chamber having an inlet;
vertically orienting the mixing chamber relative to the vacuum pump;
providing fluid communication between the outlet of the vacuum pump and the inlet of the mixing chamber;
directing the exhaust pumped by the vacuum pump outlet to the mixing chamber; and
maintaining the temperature of the exhaust while the exhaust is directed to the mixing chamber; and
directing water into the exhaust in the mixing chamber to remove water reactive products and/or water absorbing products in the exhaust.

38. The method according to claim 37, wherein said directing water includes injecting water into the exhaust in the mixing chamber with venturi nozzles.

39. The method according to claim 37, wherein said removing water reactive byproducts includes removing a water reactive product selected from the group consisting of titanium tetrachloride, tungsten hexafluoride, ammonium nitrate, trimethyl aluminum, and chlorine trifluoride.
